(19) United States
(12) Patent Application Publication
(10) Pub. No.: US 2023/0048867 A1
(43) Pub. Date: Feb. 16, 2023

(54) VEHICULAR CAMERA DEVICE

(71) Applicant: KABUSHIKI KAISHA TOKAI-RIKA-DENKI-SEISAKUSHO, Niwa-gun, Aichi (JP)

(72) Inventors: Kenichi SUGISAKA, Niwa-gun, Aichi (JP); Masakazu IWATSUKI, Niwa-gun, Aichi (JP); Tomonori ICHIKAWA, Niwa-gun, Aichi (JP); Takehiro HAMADA, Niwa-gun, Aichi (JP); Tomohiro NAKAO, Niwa-gun, Aichi (JP); Ryusuke SADAMATSU, Niwa-gun, Aichi (JP); Suguru FUJISAKI, Niwa-gun, Aichi (JP)

(21) Appl. No.: 17/796,402

(22) PCT Filed: Dec. 10, 2020
(86) PCT No.: PCT/JP2020/046085

§ 371 Date: Jul. 29, 2022

(30) Foreign Application Priority Data
Jan. 30, 2020 (JP) 2020-013891

(51) Int. Cl. B60R 1/12; B60R 1/06; B60R 11/04; H04N 5/225; G03B 17/55; H05K 7/20

(52) U.S. Cl. CPC B60R 1/12; B60R 1/06; B60R 11/04; H04N 5/2253; H04N 5/2252; G03B 17/55; H05K 7/2039; B60R 2001/1253; B60R 2011/004

(57) ABSTRACT

In a vehicle camera device, a camera is housed inside a bracket of a base, and a stud bolt of the base is connected to a side door. Heat generated by the camera is transferred to the side door via the bracket, the base, and the stud bolt. Therefore, the heat generated by the camera can be efficiently released from the camera.

### TECHNICAL FIELD

The present invention relates to a vehicle camera device in which a camera mechanism is configured to be able to perform imaging.

### BACKGROUND ART

In a door mirror described in Japanese Patent Application Laid-Open (JP-A) No. 2006-103680, a mirror fixing portion is supported by a vehicle body side, and a covering cap, which has a shell shape, covers the mirror fixing portion. In the covering cap, a holder cage is fixed. A wall portion of the holding cage surrounds the periphery of the camera, and a bottom portion of the holding cage supports the camera.

In such a door mirror, it is preferable that heat generated by the camera can be excellently released from the camera.

### SUMMARY OF INVENTION

### Technical Problem

In view of the fact, an object of the present invention is to obtain a vehicle camera device in which heat generated by a camera mechanism can be efficiently released from the camera mechanism.

### Solution to Problem

A vehicle camera device according to a first aspect of the invention includes a support body that is provided with a connection portion connected to a vehicle body side, and that is supported by the vehicle body side, and a camera mechanism that is configured to perform imaging, and heat generated by the camera mechanism being transferred to the vehicle body side via the connection portion.

A vehicle camera device according to a second aspect of the invention is the vehicle camera device according to the first aspect of the invention, and further includes an attachment portion that is provided at the support body, to which the camera mechanism is attached, whereupon the camera mechanism is attached to the support body, and that is configured to transfer the heat generated by the camera mechanism to a side of the connection portion.

A vehicle camera device according to a third aspect of the invention is the vehicle camera device according to the second aspect of the invention, in which the attachment portion is attached to the support body by a biasing force.

A vehicle camera device according to a fourth aspect of the invention is the vehicle camera device according to any one of the first to third aspects of the invention, and further includes a connection member that is connected to the camera mechanism, and that is configured to transfer the heat generated by the camera mechanism to a side of the connection portion.

A vehicle camera device according to a fifth aspect of the invention is the vehicle camera device according to the fourth aspect of the invention, in which the connection member is connected to the camera mechanism by a biasing force.

A vehicle camera device according to a sixth aspect of the invention includes a support body that is supported by a vehicle body side, a covering body that is configured to cover the support body, and a camera mechanism that is provided adjacent to an outer peripheral wall of the covering body, in the covering body, that is configured to perform imaging, and heat generated by the camera mechanism being transferred to an outside of the covering body via the outer peripheral wall of the covering body.

A vehicle camera device according to a seventh aspect of the invention is the vehicle camera device according to the sixth aspect of the invention, and further includes plural component bodies each of which is a component of the covering body, and between which the camera mechanism is assembled, whereupon the camera mechanism is attached to the covering body.

A vehicle camera device according to an eighth aspect of the invention is the vehicle camera device according to the seventh aspect of the invention, and further includes a covering portion that is provided at the outer peripheral wall of the covering body, and that is configured to cover a portion at which the camera mechanism is assembled between the plural component bodies.

A vehicle camera device according to a ninth aspect of the invention is the vehicle camera device according to any one of the sixth to eighth aspects of the invention, and further includes an arrangement body that is arranged outside the covering body. The outer peripheral wall of the covering body is arranged between the arrangement body and the camera mechanism.

### Advantageous Effects of Invention

In the vehicle camera device according to the first aspect of the invention, the support body is supported by the vehicle body side, and the camera mechanism is configured to be able to perform imaging.

Here, the connection portion of the support body is connected to the vehicle body side, and the heat generated by the camera mechanism is transferred to the vehicle body side via the connection portion. Thus, the heat generated by the camera mechanism can be efficiently released from the camera mechanism.

In the vehicle camera device according to the second aspect of the invention, the camera mechanism is attached to the attachment portion of the support body, whereupon the camera mechanism is attached to the support body.

Here, the attachment portion, via which the camera mechanism is attached to the support body, transfers the heat generated by the camera mechanism to the side of the connection portion. Thus, the heat generated by the camera mechanism can be transferred to the side of the connection portion with a simple configuration.

In the vehicle camera device according to the third aspect of the invention, the attachment portion is attached to the support body by the biasing force. Thus, the attachment portion can be easily attached to the support body.

In the vehicle camera device according to the fourth aspect of the invention, the connection member, which is connected to the camera mechanism, transfers the heat generated by the camera mechanism to the side of the connection portion. Thus, the heat generated by the camera mechanism can be easily transferred to the side of the connection portion.

In the vehicle camera device according to the fifth aspect of the invention, the connection member is connected to the camera mechanism by the biasing force. Thus, the connection member can be easily connected to the camera mechanism.

In the vehicle camera device according to the sixth aspect of the invention, the support body is supported by the vehicle body side, and the covering body covers the support body. The camera mechanism is configured to be able to perform imaging.

Here, the camera mechanism is provided adjacent to the outer peripheral wall of the covering body, in the covering body. The heat generated by the camera mechanism is transferred to the outside of the covering body via the outer peripheral wall of the covering body. Thus, the heat generated by the camera mechanism can be efficiently released from the camera mechanism.

In the vehicle camera device according to the seventh aspect of the invention, the plural component bodies are included in the covering body as components.

Here, the camera mechanism is assembled between the component bodies, whereupon the camera mechanism is attached to the covering body. Therefore, the camera mechanism can be easily attached to the covering body.

In the vehicle camera device according to the eighth aspect of the invention, the covering portion of the outer peripheral wall of the covering body covers the portion at which the camera mechanism is assembled between the component bodies. Thus, it is possible to prevent the portion at which the camera mechanism is assembled between the component bodies from being viewed.

In the vehicle camera device according to the ninth aspect of the invention, the arrangement body is arranged outside the covering body. The outer peripheral wall of the covering body is arranged between the arrangement body and the camera mechanism. Thus, the heat generated by the camera mechanism can be transferred between the outer peripheral wall of the covering body and the arrangement body.

### BRIEF DESCRIPTION OF DRAWINGS

FIG. 1 is a front view showing a vehicle camera device according to a first embodiment of the present invention, as viewed from the vehicle rear side.

FIG. 2A is a view showing main portions of the vehicle camera device according to the first embodiment of the invention, and is a cross-sectional view as viewed from the vehicle rear side.

FIG. 2B is a view showing the main portions of the vehicle camera device according to the first embodiment of the invention, and is a cross-sectional view (a cross-sectional view taken along line 2B-2B in FIG. 2A) as viewed from a vehicle width direction outer side.

FIG. 3A is a cross-sectional view showing main portions of a vehicle camera device according to a second embodiment of the invention, as viewed from the vehicle rear side.

FIG. 3B is a cross-sectional view showing main portions of a vehicle camera device according to a third embodiment of the invention, as viewed from the vehicle rear side.

FIG. 3C is a cross-sectional view showing main portions of a vehicle camera device according to a fourth embodiment of the invention, as viewed from the vehicle rear side.

FIG. 4A is a view showing main portions of a vehicle camera device according to a fifth embodiment of the invention, and is a cross-sectional view as viewed from the vehicle rear side.

FIG. 4B is a view showing the main portions of the vehicle camera device according to the fifth embodiment of the invention, and is a cross-sectional view (a cross-sectional view taken along line 4B-4B in FIG. 4A) as viewed from the vehicle width direction outer side.

FIG. 5 is an exploded perspective view showing main portions of a vehicle camera device according to a sixth embodiment of the invention, as viewed from the vehicle rear side and the vehicle width direction outer side.

### DESCRIPTION OF EMBODIMENTS

### First Embodiment

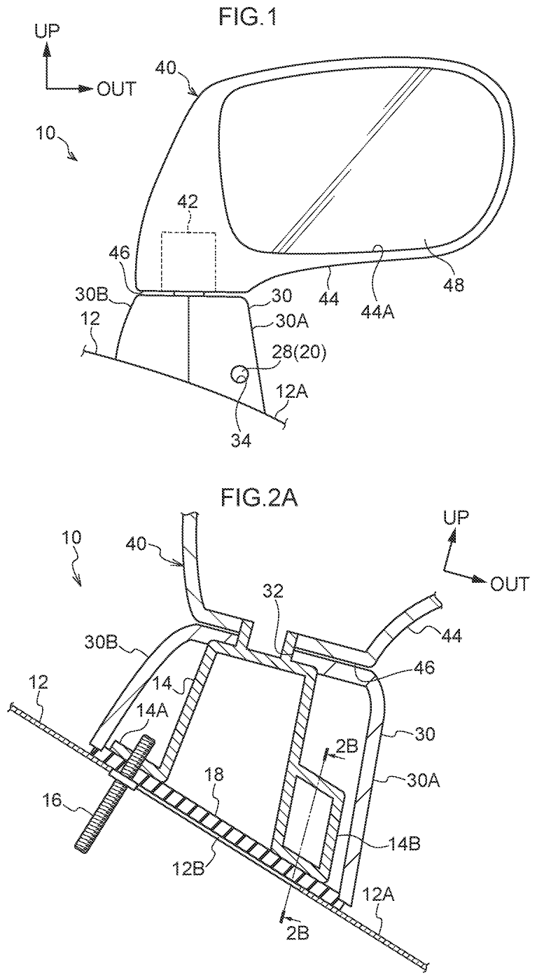

In FIG. 1, a vehicle camera device 10 according to a first embodiment of the present invention is shown in a front view as viewed from a vehicle rear side. In the drawings, the vehicle front side is indicated by arrow FR, a vehicle width direction outer side (the vehicle right side) is indicated by arrow OUT, and the upper side is indicated by arrow UP.

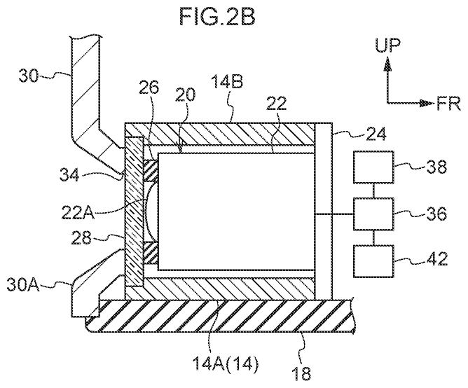

As shown in FIG. 1, the vehicle camera device 10 according to the present embodiment is installed on a side door 12 (specifically, a front side door), which serves as a vehicle body side of a vehicle. An outer panel 12A, which is made of a metal and has a plate shape, and serves as an outer peripheral member, is provided at a vehicle width direction outer side end of a lower side portion of the side door 12. The outer panel 12A forms an outer peripheral surface on the vehicle exterior side in the lower side portion of the side door 12. A fixing panel (not shown in the drawings), which is made of a metal and has a plate shape, and serves as an inner member (a transfer member), is fixed in the lower side portion of the side door 12. An insertion hole 12B (see FIG. 2A), which has a substantially circular shape, is formed penetrating through an end portion on the vehicle front side and the upper side of the outer panel 12A. The fixing panel is open to the vehicle exterior side of the outer panel 12A via the insertion hole 12B.

The vehicle camera device 10 is provided with a base 14 (see FIG. 2A), which has a bottomed, substantially circular tube shape, and serves as a support body. The inside of the base 14 is open to the lower side. The base 14 is made of a metal (for example, aluminum), and has enhanced rigidity and thermal conductivity. A fixing plate 14A, which has a substantially annular plate shape, is integrally formed at a lower end of the base 14. The fixing plate 14A protrudes toward the outside of the outer periphery of the base 14. A bracket 14B (a housing), which has a rectangular tube shape and serves as an attachment portion, is integrally formed at a lower portion in a vehicle width direction outer side portion of the base 14. A vehicle width direction inner side wall of the bracket 14B is included in a peripheral wall of the base 14, and a lower wall of the bracket 14B is included in the fixing plate 14A. The axial direction of the bracket 14B is arranged parallel to the vehicle front-rear direction, and the inside of the bracket 14B is open to the vehicle front side and the vehicle rear side.

A predetermined number of stud bolts 16, each of which has a substantially rod shape and serves as a connection portion, are fixed to the fixing plate 14A, and the vicinity of an upper end portion of each of the stud bolts 16 penetrates through the fixing plate 14A. Each of the stud bolts 16 is made of a metal, and has enhanced rigidity and thermal conductivity.

A seal 18, which has a substantially circular plate shape, is provided below the base 14. The seal 18 is made of a rubber, and has elasticity and sealing performance. The seal 18 covers the lower side of the base 14 (including the fixing plate 14A), and the stud bolts 16 of the base 14 penetrate through the seal 18. The seal 18 covers the upper side of the insertion hole 12B and a peripheral portion of the insertion hole 12B in the outer panel 12A of the side door 12, and the base 14 is supported by the outer panel 12A via the seal 18. The stud bolts 16 are inserted in the insertion hole 12B, and a lower portion of each of the stud bolts 16 is fastened and fixed (connected) to the fixing panel of the side door 12. As a result, the base 14 is attached to the side door 12, and the vehicle camera device 10 is installed on the side door 12.

A camera mechanism 20 (see FIG. 2B) is attached to the bracket 14B of the base 14.

As shown in FIG. 2B, the camera mechanism 20 is provided with a camera 22, which has a substantially rectangular pillar shape. The camera 22 is coaxially housed inside the bracket 14B. A lens 22A is coaxially provided in a vehicle rear side end portion of the camera 22, and the lens 22A is exposed to the vehicle rear side.

An attachment plate 24, which is made of a resin and has a rectangular plate shape, and serves as an attachment member, is fixed at the vehicle front side of the camera 22. The attachment plate 24 protrudes toward the upper side, the lower side, and the vehicle width direction outer side from the camera 22. The attachment plate 24 is attached to the vehicle front side of the bracket 14B. As a result, the camera 22 is fixed inside the bracket 14B.

A double-sided tape 26, which has an annular plate shape and serves as an adhesive member, coaxially adheres to a vehicle rear side surface of the camera 22. The inside of the double-sided tape 26 allows the lens 22A of the camera 22 to be exposed to the vehicle rear side. A cover glass 28, which has a rectangular plate shape and serves as a transmissive member, is coaxially adheres to the vehicle rear side of the double-sided tape 26. The cover glass 28 is coaxially fitted inside a vehicle rear side end portion of the bracket 14B. The cover glass 28 is made transparent, and is configured to be able to transmit light.

The base 14 and the camera mechanism 20 are covered by a base cover 30 (see FIG. 2A), which is made of a resin and has a substantially bottomed circular tube shape, and serves as a covering body. The base cover 30 has an inside, which is open to the lower side, and the base cover 30 is fixed to the base 14. The base cover 30 is configured by combining (fitting) a first cover 30A, which serves as a component body on the vehicle width direction outer side, and a second cover 30B, which serves as a component body on the vehicle width direction inner side. An open hole 32, which has a substantially circular shape, is formed penetrating through a central portion of an upper wall of the base cover 30. The open hole 32 is defined by the first cover 30A and the second cover 30B, and allows an upper wall of the base 14 to be open to the upper side.

In the base cover 30, an aperture 34 (see FIG. 2B), which has a circular shape, is formed penetrating through a lower portion on the vehicle width direction outer side and the vehicle rear side of the first cover 30A. The aperture 34 allows the inside of the base cover 30 to be open to the vehicle rear side. The cover glass 28 of the camera mechanism 20 is brought into abutment on an inner surface of the base cover 30 at a peripheral portion of the aperture 34. The aperture 34 is arranged coaxially with the cover glass 28.

The aperture 34 coaxially faces the lens 22A of the camera 22 via the cover glass 28. The camera 22 is configured to be able to image the vehicle rear side (the outside of the aperture 34 of the base cover 30) via the aperture 34, the cover glass 28, and the lens 22A. The camera 22 is electrically connected to a controller 36 of the vehicle. The camera 22 is operated by control of the controller 36, as a result of which the camera 22 images the vehicle rear side. A monitor 38, which serves as a display mechanism, is electrically connected to the controller 36, and the monitor 38 displays an image imaged by the camera 22 under control of the controller 36. The monitor 38 is installed in a vehicle cabin. An occupant (specifically, a driver) of the vehicle is assisted in viewing the vehicle rear side by looking at an image displayed on the monitor 38.

The entire periphery of a lower end of the base cover 30 holds the seal 18 in a pinching manner, between the entire periphery of the lower end of the base cover 30 and the outer panel 12A of the side door 12. The seal 18 is compressed between the lower end of the base cover 30 and the outer panel 12A. As a result, sealing is made by the seal 18 between the lower end of the base cover 30 and the outer panel 12A.

A mirror mechanism 40 is supported on the vehicle upper side of the base 14 via the open hole 32 of the base cover 30.

The mirror mechanism 40 is provided with a retraction mechanism 42, which is supported by the base 14 via the open hole 32. The retraction mechanism 42 supports a visor 44, which has a substantially rectangular parallelepiped box shape and serves as an arrangement body. The retraction mechanism 42 penetrates through a lower wall in a vehicle width direction inner side end portion of the visor 44, and is fixed inside the vehicle width direction inner side end portion of the visor 44. The lower wall of the vehicle width direction inner side end portion of the visor 44 faces the upper wall of the base cover 30 in the vertical direction, as a result of which a gap 46 is formed between the lower wall of the vehicle width direction inner side end portion of the visor 44 and the upper wall of the base cover 30. The gap 46 has a reduced vertical dimension. An exposure hole 44A, which has a substantially rectangular shape, is formed penetrating through a vehicle rear side wall of the visor 44. A mirror 48, which has a substantially rectangular plate shape, is disposed in the exposure hole 44A. The mirror 48 is supported in the visor 44, and has a front surface, which is exposed to the vehicle rear side from the exposure hole 44A. The occupant is assisted in viewing the vehicle rear side by looking at light reflected from the mirror 48, from the front side of the mirror 48.

The retraction mechanism 42 is electrically connected to the controller 36. The retraction mechanism 42 is operated by control of the controller 36, as a result of which the retraction mechanism 42 causes the visor 44 and the mirror 48 to rotate toward the vehicle rear side and the vehicle front side with respect to the base 14 and the base cover 30. Therefore, the visor 44 and the mirror 48 are caused to rotate to the vehicle rear side to be retracted, and the visor 44 and the mirror 48 are caused to rotate to the vehicle front side to be deployed (returned).

Next, operation of the present embodiment will be described.

In the vehicle camera device 10 having the configuration described above, the camera 22 of the camera mechanism 20 is operated, as a result of which the camera 22 images the vehicle rear side via the aperture 34 of the base cover 30, the cover glass 28, and the lens 22A of the camera 22. The occupant of the vehicle is assisted in viewing the vehicle rear side by looking at an image imaged by the camera 22 and displayed on the monitor 38. After the camera 22 is operated, the camera 22 generates heat.

Here, the camera 22 is housed inside the bracket 14B of the base 14, and the stud bolts 16 of the base 14 are connected to the side door 12 (the fixing panel). As a result, the heat generated by the camera 22 is transferred to the side door 12 via the bracket 14B, the base 14, and the stud bolts 16. Therefore, the heat generated by the camera 22 can be efficiently released from the camera 22, and the camera 22 can be excellently operated.

The bracket 14B, via which the camera 22 is attached to the base 14, transfers the heat generated by the camera 22 to the stud bolts 16 via the base 14. Thus, the heat generated by the camera 22 can be transferred to the stud bolts 16 with a simple configuration.

The bracket 14B, to which the camera 22 can be attached, is integrally provided at the base 14. Thus, vibration of the camera 22 can be reduced during traveling of the vehicle, stability of the camera 22 can be ensured, and visibility for the occupant with respect to the vehicle rear side can be stabilized.

In the present embodiment, the camera 22 may be brought into contact (specifically, surface contact) with the bracket 14B of the base 14.

### Second Embodiment

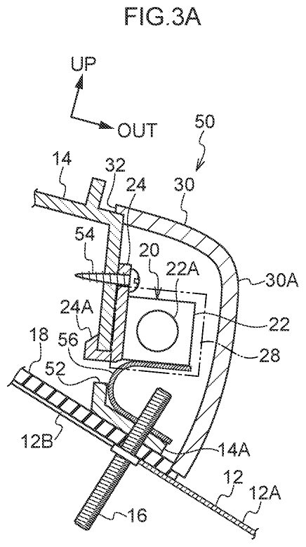

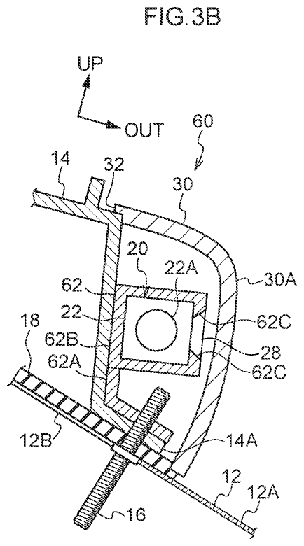

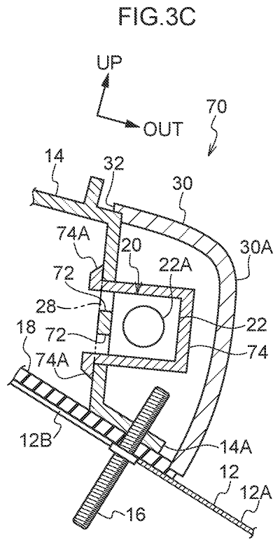

In FIG. 3A, main portions of a vehicle camera device 50 according to a second embodiment of the invention are shown in a cross-sectional view as viewed from the vehicle rear side.

The vehicle camera device 50 according to the present embodiment has a configuration substantially similar to that of the first embodiment, but differs in the following points.

In the vehicle camera device 50 according to the present embodiment, the base 14 is made of a resin, as shown in FIG. 3A. The bracket 14B is not formed at the base 14, and a holding hole 52, which has a rectangular shape, is formed penetrating through the lower portion in the vehicle width direction outer side portion of the peripheral wall of the base 14.

In the camera mechanism 20, the attachment plate 24 is fixed on the vehicle width direction inner side of the camera 22. An upper portion of the attachment plate 24 protrudes toward the upper side from the camera 22. The upper portion of the attachment plate 24 is fastened on the vehicle width direction outer side portion in the peripheral wall of the base 14 with a predetermined number of fastening screws 54. As a result, the camera 22 is attached to a vertically intermediate portion of the vehicle width direction outer side portion of the base 14. A portion excluding the upper portion of the attachment plate 24 is formed as a hook portion 24A, which has a J-shaped cross section. The hook portion 24A has a lower end portion, which protrudes toward the vehicle width direction inner side, and a tip portion (a vehicle width direction inner side portion), which protrudes toward the upper side. A portion, on the upper side with respect to the holding hole 52, of the peripheral wall of the base 14 is fitted in the hook portion 24A. The hook portion 24A restricts movement of the camera 22 toward the vehicle width direction outer side.

A plate spring 56, which has a rectangular plate shape and serves as a connection member, extends between a lower surface of the camera 22 and an upper surface of the fixing plate 14A of the base 14. The plate spring 56 is made of a metal, and has enhanced elasticity and thermal conductivity. An intermediate portion of the plate spring 56 is elastically deformed into a U-shaped cross section. The plate spring 56 has a lower portion, through which the upper end portion of the stud bolt 16 of the base 14 penetrates and is fitted, and which is brought into abutment on (surface contact with) the upper surface of the fixing plate 14A by a biasing force of the plate spring 56. An upper portion of the plate spring 56 is brought into abutment on (surface contact with) the lower surface of the camera 22 by the biasing force of the plate spring 56. The plate spring 56 biases the camera 22 and the attachment plate 24 toward the upper side, thereby holding the fitting state of the hook portion 24A of the attachment plate 24 to the peripheral wall of the base 14.

In the base cover 30, the aperture 34 is formed penetrating through a vertically intermediate portion on the vehicle width direction outer side and the vehicle rear side of the first cover 30A. The aperture 34 coaxially faces the lens 22A of the camera 22 via the cover glass 28 of the camera mechanism 20.

Here, the camera 22 is connected to the stud bolt 16 of the base 14 via the plate spring 56, and the stud bolt 16 is connected to the side door 12 (the fixing panel). As a result, heat generated by the camera 22 is transferred to the side door 12 via the plate spring 56 and the stud bolt 16. Therefore, the heat generated by the camera 22 can be efficiently released from the camera 22, and the camera 22 can be excellently operated.

The plate spring 56, which is connected to the camera 22, transfers the heat generated by the camera 22 to the stud bolt 16. Thus, the heat generated by the camera 22 can be easily transferred to the stud bolt 16.

The plate spring 56 connects the camera 22 and the stud bolt 16 via the biasing force. Thus, the plate spring 56 can easily connect the camera 22 and the stud bolt 16.

In a case in which the camera 22 is attached to the base 14, the tip portion of the hook portion 24A of the attachment plate 24 in the camera 22 is caused to pass through the holding hole 52 of the peripheral wall of the base 14 toward the vehicle width direction inner side. As a result, the hook portion 24A is fitted to the peripheral wall of the base 14. Then, the intermediate portion of the plate spring 56 is elastically deformed. The stud bolt 16 of the base 14 penetrates through the lower portion of the plate spring 56, and the lower portion of the plate spring 56 is brought into abutment on the upper surface of the fixing plate 14A of the base 14. The upper portion of the plate spring 56 is brought into abutment on the lower surface of the camera 22. As a result, the camera 22 and the attachment plate 24 are biased toward the upper side by the plate spring 56. The upper portion of the attachment plate 24 is fastened onto the peripheral wall of the base 14 with the predetermined number of fastening screws 54.

In a case in which the camera 22 is attached to the base 14, the camera 22 and the attachment plate 24 are biased toward the upper side by the plate spring 56. Then, the fitting state of the hook portion 24A to the peripheral wall of the base 14 is held by the biasing force of the plate spring 56. As a result, the camera 22 and the attachment plate 24 are temporarily fixed to the peripheral wall of the base 14. Thus, the upper portion of the attachment plate 24 can be easily fastened onto the peripheral wall of the base 14 with the predetermined number of fastening screws 54.

The fitting state of the hook portion 24A to the peripheral wall of the base 14 is held by the biasing force of the plate spring 56. Thus, it is possible to reduce the number of fastening positions at which the upper portion of the attachment plate 24 is fastened onto the peripheral wall of the base 14 with the fastening screws 54, and therefore it is possible to reduce the number of components.

### Third Embodiment

In FIG. 3B, main portions of a vehicle camera device 60 according to a third embodiment of the invention are shown in a cross-sectional view as viewed from the vehicle rear side.

The vehicle camera device 60 according to the present embodiment has a configuration substantially similar to that of the first embodiment, but differs in the following points.

In the vehicle camera device 60 according to the present embodiment, the base 14 is made of a resin, as shown in FIG. 3B.

The bracket 14B is not formed at the base 14, and a case 62, which serves as an attachment portion and a connection member, is attached to the vehicle width direction outer side portion of the base 14. The case 62 is made of a metal (for example, aluminum), and has enhanced rigidity and thermal conductivity.

An attachment piece 62A, which has a plate shape having a substantially L-shaped cross section, is formed in a lower side portion of the case 62. A lower side portion of the attachment piece 62A extends toward the vehicle width direction outer side. The upper end portion of the stud bolt 16 of the base 14 penetrates through and is fixed to the lower side portion of the attachment piece 62A. The lower side portion of the attachment piece 62A is brought into abutment on the upper surface of the fixing plate 14A of the base 14. As a result, the case 62 is attached to the stud bolt 16. An upper side portion of the attachment piece 62A extends toward the upper side, and is brought into abutment on a peripheral wall of the case 62.

An attachment frame 62B, which has a frame shape having a substantially U-shaped cross section, is formed in an upper side portion of the case 62. The inside of the attachment frame 62B is open to the vehicle width direction outer side. A lower end of a vehicle width direction inner side wall of the attachment frame 62B is integrated with an upper end of the attachment piece 62A. The vehicle width direction inner side wall of the attachment frame 62B is brought into abutment on the peripheral wall of the case 62. Locking claws 62C, each of which has a plate shape having a trapezoidal cross section, are integrally formed at respective vehicle width direction outer side end portions of an upper wall and a lower wall of the attachment frame 62B. The locking claws 62C on the upper side and on the lower side protrude toward the lower side and the upper side, respectively.

In the camera mechanism 20, the camera 22 is coaxially fitted inside the attachment frame 62B of the case 62, and movement of the camera 22 toward the vehicle width direction outer side is locked by the locking claws 62C of the attachment frame 62B. The camera 22 is brought into surface contact with the attachment frame 62B, and is disposed on the vehicle width direction outside of the vertically intermediate portion of the base 14. The attachment plate 24 in the camera 22 protrudes toward the upper side, the lower side, and both sides in the vehicle width direction from the camera 22. The attachment plate 24 is attached to the vehicle front side of the attachment frame 62B, and thus the camera 22 is fixed inside the attachment frame 62B.

In the base cover 30, the aperture 34 is formed penetrating through the vertically intermediate portion on the vehicle width direction outer side and the vehicle rear side of the first cover 30A. The aperture 34 coaxially faces the lens 22A of the camera 22 via the cover glass 28 of the camera mechanism 20.

Here, the camera 22 is connected to the stud bolt 16 of the base 14 via the case 62 (the attachment frame 62B and the attachment piece 62A), and the stud bolt 16 is connected to the side door 12 (fixing panel). As a result, heat generated by the camera 22 is transferred to the side door 12 via the plate spring 56 and the stud bolt 16. Therefore, the heat generated by the camera 22 can be efficiently released from the camera 22, and the camera 22 can be excellently operated.

The case 62, via which the camera 22 is attached to the base 14, transfers the heat generated by the camera 22 to the stud bolt 16. Thus, the heat generated by the camera 22 can be transferred to the stud bolt 16 with a simple configuration.

The case 62, which is connected to the camera 22 and the stud bolt 16, transfers the heat generated by the camera 22 to the stud bolt 16. Thus, the heat generated by the camera 22 can be easily transferred to the stud bolt 16.

### Fourth Embodiment

In FIG. 3C, main portions of a vehicle camera device 70 according to a fourth embodiment of the invention are shown in a cross-sectional view as viewed from the vehicle rear side.

The vehicle camera device 70 according to the present embodiment has a configuration substantially similar to that of the first embodiment, but differs in the following points.

In the vehicle camera device 70 according to the present embodiment, the bracket 14B is not formed at the base 14, and attachment holes 72, each of which has a rectangular shape, are formed penetrating through an upper end and a lower end of the vertically intermediate portion in the vehicle width direction outer side portion of the peripheral wall of the base 14, as shown in FIG. 3C.

An attachment spring 74, which serves as an attachment portion and a connection member, is attached to the vehicle width direction outer side portion of the base 14. The attachment spring 74 is made of a metal, and has enhanced elasticity and thermal conductivity. The attachment spring 74 has a frame shape having a substantially U-shaped cross section, and the inside of the attachment spring 74 is open to the vehicle width direction inner side. Attachment claws 74A, each of which has a plate shape having a trapezoidal cross section, are integrally formed at respective vehicle width direction inner side end portions of an upper wall and a lower wall of the attachment spring 74. The attachment claws 74A on the upper side and on the lower side protrude toward the upper side and the lower side, respectively. The upper wall and the lower wall of the attachment spring 74 are brought close to each other by elastic deformation, and the attachment claws 74A on the upper side and on the lower side are caused to pass through the respective attachment holes 72, on the upper side and on the lower side, of the peripheral wall of the base 14 toward the vehicle width direction inner side. The upper wall and the lower wall of the attachment spring 74 are brought into abutment on an upper surface of the attachment hole 72 on the upper side and a lower surface of the attachment hole 72 on the lower side, respectively, by a biasing force, and the attachment claws 74A are brought into abutment on an inner surface of the peripheral wall of the base 14. Thus, movement of the attachment spring 74 in the vertical direction and toward the vehicle width direction outer side is restricted by the peripheral wall of the base 14, and the attachment spring 74 is attached to the vehicle width direction outer side portion of the peripheral wall of the base 14.

In the camera mechanism 20, the camera 22 is fitted inside the attachment spring 74, and movement of the camera 22 toward the vehicle width direction inner side is locked by the peripheral wall of the base 14. The camera 22 is brought into surface contact with the attachment spring 74 and the peripheral wall of the base 14, and is disposed on the vehicle width direction outside of the vertically intermediate portion of the base 14. The camera 22 restricts a mutual approach of the upper wall and the lower wall of the attachment spring 74. As a result, the attachment claws 74A are restricted from passing through the attachment holes 72 of the peripheral wall of the base 14 toward the vehicle width direction outer side, and detachment of the attachment spring 74 from the peripheral wall of the base 14 is restricted. The attachment plate 24 in the camera 22 protrudes toward the upper side, the lower side, and the vehicle width direction outer side from the camera 22. The attachment plate 24 is attached to the vehicle front side of the attachment spring 74, and thus the camera 22 is fixed inside the attachment spring 74.

In the base cover 30, the aperture 34 is formed penetrating through the vertically intermediate portion on the vehicle width direction outer side and the vehicle rear side of the first cover 30A. The aperture 34 coaxially faces the lens 22A of the camera 22 via the cover glass 28 of the camera mechanism 20.

Here, the camera 22 is connected to the stud bolt 16 of the base 14 via the attachment spring 74 and the base 14, or via the base 14, and the stud bolt 16 is connected to the side door 12 (the fixing panel). Thus, heat generated by the camera 22 is transferred to the side door 12 via the attachment spring 74, the base 14, and the stud bolt 16, or via the base 14 and the stud bolt 16. Therefore, the heat generated by the camera 22 can be efficiently released from the camera 22, and the camera 22 can be excellently operated.

The attachment spring 74, via which the camera 22 is attached to the base 14, transfers the heat generated by the camera 22 to the stud bolt 16 via the base 14. Thus, the heat generated by the camera 22 can be transferred to the stud bolt 16 with a simple configuration.

The attachment spring 74, which is connected to the camera 22 and the base 14, transfers the heat generated by the camera 22 to the stud bolt 16 via the base 14. Thus, the heat generated by the camera 22 can be easily transferred to the stud bolt 16.

The attachment claws 74A of the attachment spring 74 are engaged with the peripheral wall of the base 14 by the biasing force of the attachment spring 74, and thus the attachment spring 74 is attached to the base 14. Therefore, the attachment spring 74 can be easily attached to the base 14.

The camera 22 is fixed while being brought into contact with the peripheral wall of the base 14 by the attachment spring 74. Thus, vibration of the camera 22 can be reduced during traveling of the vehicle, stability of the camera 22 can be ensured, and visibility for the occupant with respect to the vehicle rear side can be stabilized.

In the first to fourth embodiments, the camera mechanism 20 is separated from the stud bolt 16 of the base 14. However, the camera mechanism 20 (specifically, the camera 22) may be brought into contact with the stud bolt 16 of the base 14.

### Fifth Embodiment

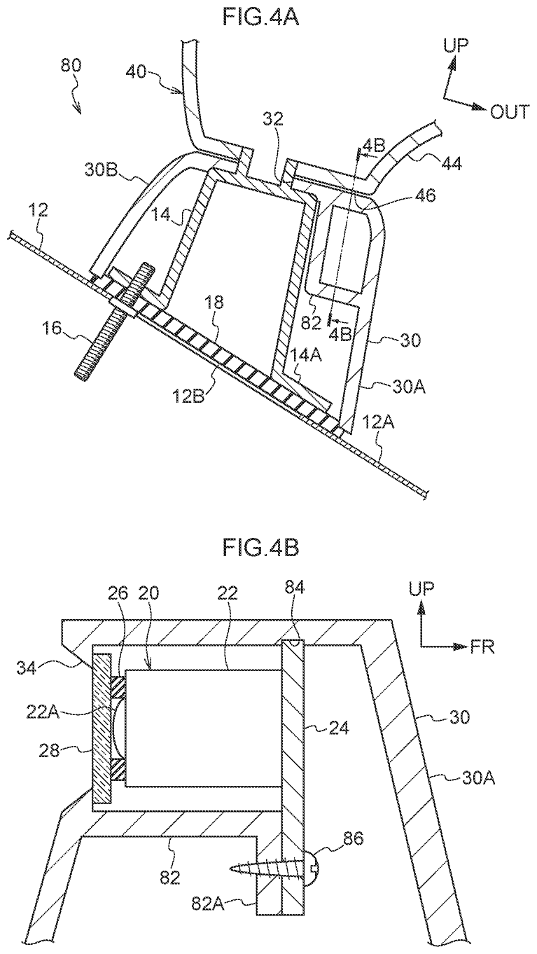

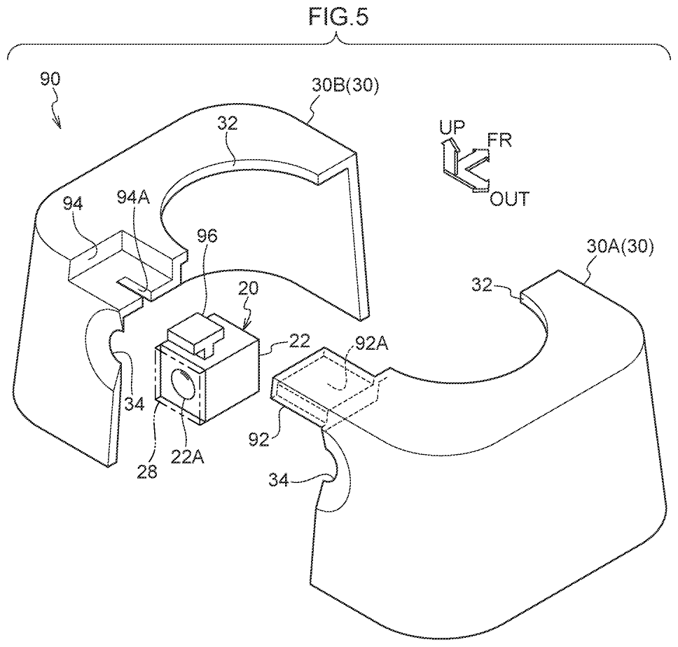

In FIG. 4A, main portions of a vehicle camera device 80 according to a fifth embodiment of the invention are shown in a cross-sectional view as viewed from the vehicle rear side. In FIG. 4B, the main portions of the vehicle camera device 80 are shown in a cross-sectional view (a cross-sectional view taken along line 4B-4B in FIG. 4A) as viewed from the vehicle width direction outer side.

The vehicle camera device 80 according to the present embodiment has a configuration substantially similar to that of the first embodiment, but differs in the following points.

In the vehicle camera device 80 according to the present embodiment, the bracket 14B is not formed at the base 14, as shown in FIG. 4A.

As shown in (A) and (B) of FIG. 4, an arrangement tube 82 (a housing), which has a rectangular tube shape and serves as an arrangement portion, is integrally formed at an upper portion of a vehicle width direction outer side portion of the base cover 30 (the first cover 30A). An upper wall of the arrangement tube 82 is included in the upper wall (an outer peripheral wall) of the base cover 30, and a vehicle width direction outer side wall of the arrangement tube 82 is included in a peripheral wall (an outer peripheral wall) of the base cover 30. The axial direction of the arrangement tube 82 is arranged parallel to the vehicle front-rear direction, and the inside of the arrangement tube 82 is open to the vehicle front side. The aperture 34 is formed penetrating through an upper portion on the vehicle width direction outer side and the vehicle rear side of the first cover 30A. The aperture 34 allows the inside of the arrangement tube 82 to be open to the vehicle rear side.

An arrangement plate 82A, which has a rectangular plate shape, is integrally formed at a vehicle front side end portion of a lower wall of the arrangement tube 82. The arrangement plate 82A extends toward the lower side, and is arranged perpendicular to the vehicle front-rear direction. An arrangement groove 84, which has a rectangular cross section, is formed on a lower surface of the upper wall of the base cover 30. The arrangement groove 84 extends in the vehicle width direction, and is adjacent to the vehicle front side of the arrangement tube 82.

In the camera mechanism 20, the camera 22 is coaxially housed inside the arrangement tube 82 of the base cover 30. The attachment plate 24 in the camera 22 protrudes toward the upper side, the lower side, and the vehicle width direction inner side from the camera 22. An upper end portion of the attachment plate 24 is fitted into the arrangement groove 84 of the base cover 30, and a lower portion of the attachment plate 24 is fastened on the arrangement plate 82A of the base cover 30 with an attachment screw 86. As a result, the attachment plate 24 is attached to the vehicle front side of the arrangement tube 82, and the camera 22 is fixed inside the arrangement tube 82. The lens 22A of the camera 22 coaxially faces the aperture 34 of the base cover 30 via the cover glass 28.

Here, the camera 22 of the camera mechanism 20 is provided adjacent to the upper wall and the peripheral wall of the base cover 30, in the base cover 30 (in the arrangement tube 82). Thus, heat generated by the camera 22 is transferred to the outside of the base cover 30 via the upper wall and the peripheral wall of the base cover 30. Therefore, the heat generated by the camera 22 can be efficiently released from the camera 22 through natural convection of the air outside of the base cover 30, and the camera 22 can be excellently operated.

The heat generated by the camera 22 is transferred to the gap 46 between the upper wall of the base cover 30 and the lower wall of the visor 44 of the mirror mechanism 40 via the upper wall of the base cover 30. Thus, even in a case in which freezing occurs in the gap 46 between the upper wall of the base cover 30 and the lower wall of the visor 44, the freezing can be melted by the heat generated by the camera 22. Therefore, it is possible to prevent restriction, due to the freezing, on the rotation of the visor 44 and the mirror 48 occurring in conjunction with the operation of the retraction mechanism 42 in the mirror mechanism 40.

### Sixth Embodiment

In FIG. 6, main portions of a vehicle camera device 90 according to a fifth embodiment of the invention are shown in an exploded perspective view as viewed from the vehicle rear side and the vehicle width direction outer side.

The vehicle camera device 90 according to the present embodiment has a configuration substantially similar to that of the fifth embodiment, but differs in the following points.

In the vehicle camera device 90 according to the present embodiment, the arrangement tube 82, the arrangement plate 82A, and the arrangement groove 84 are not provided in the base cover 30, as shown in FIG. 6.

In the base cover 30, a covering plate 92, which has an L-shaped plate shape and serves as a covering portion, is integrally formed at an end portion on the upper side and the vehicle width direction inner side in a vehicle rear side portion of the first cover 30A. The covering plate 92 extends toward the vehicle width direction inner side. An upper surface and a vehicle rear side surface of the covering plate 92 are flush with an upper surface and a vehicle rear side surface of the first cover 30A, respectively. An upper wall and a vehicle rear side wall of the covering plate 92 are included in an upper wall and a vehicle rear side wall of the first cover 30A (the outer peripheral walls of the base cover 30), respectively. In the covering plate 92, a covering chamber 92A, which has a substantially rectangular parallelepiped shape, is formed. The covering chamber 92A is open to the vehicle width direction inner side and the vehicle front side.

An insertion chamber 94, which has a substantially rectangular parallelepiped shape, is formed at an end portion on the upper side and the vehicle width direction outer side in a vehicle rear side portion of the second cover 30B. The insertion chamber 94 is open to the vehicle rear side, the upper side, and the vehicle width direction outer side. An insertion slit 94A, which has a rectangular shape, is formed penetrating through a lower wall of the insertion chamber 94. The insertion slit 94A extends in the vehicle width direction, and is open to the vehicle width direction outer side.

The insertion chamber 94 is covered by the covering plate 92 of the first cover 30A by fitting the covering plate 92 to the insertion chamber 94. The upper surface and the vehicle rear side surface of the covering plate 92 are flush with an upper surface and a vehicle rear side surface of the second cover 30B, respectively.

The aperture 34 is formed penetrating through an upper portion on the vehicle rear side and the vehicle width direction center of the base cover 30. The aperture 34 is defined by the first cover 30A and the second cover 30B.

In the camera mechanism 20, the attachment plate 24 is not fixed to the camera 22.

An attachment protrusion 96, which is made of a resin and has a pillar shape having a T-shaped cross section, and serves as an insertion portion, is integrally formed on an upper surface of the camera 22. The attachment protrusion 96 extends in the vehicle width direction. A lower side portion of the attachment protrusion 96 protrudes toward the upper side, and an upper side portion of the attachment protrusion 96 protrudes toward both sides in the vehicle front-rear direction. The lower side portion of the attachment protrusion 96 is inserted (press-fitted) into the insertion slit 94A of the second cover 30B from the vehicle width direction outer side. Then, the lower side portion of the attachment protrusion 96 is sandwiched between a vehicle front side surface and a vehicle rear side surface of the insertion slit 94A, and is sandwiched between a vehicle width direction inner side surface of the insertion slit 94A and a vehicle width direction outer side surface of the covering chamber 92A of the first cover 30A. The upper side portion of the attachment protrusion 96 is inserted into the insertion chamber 94 of the second cover 30B from the vehicle width direction outer side. Then, the lower wall of the insertion chamber 94 of the second cover 30B is sandwiched between the upper side portion of the attachment protrusion 96 and the upper surface of the camera 22. As a result, movement of the camera 22 in the vehicle front-rear direction, the vehicle width direction, and the vertical direction with respect to the base cover 30 is restricted, and thus the camera 22 is attached to the base cover 30. The lens 22A of the camera 22 coaxially faces the aperture 34 of the base cover 30 via the cover glass 28.

Operation and effects similar to those of the fifth embodiment can be achieved also in the present embodiment.

In a state in which the lower side portion of the attachment protrusion 96 of the camera 22 is inserted into the insertion slit 94A of the second cover 30B, the first cover 30A and the second cover 30B are assembled, and the covering plate 92 of the first cover 30A is fitted to the insertion chamber 94 of the second cover 30B. As a result. the camera 22 (including the attachment protrusion 96) is assembled between the first cover 30A and the second cover 30B, and thus is attached to the base cover 30. Therefore, the camera 22 can be easily attached to the base cover 30. It is also possible to eliminate the need for a screw used for attaching the camera 22 to the base cover 30, and thus it is possible to reduce the number of components.

In a state in which the upper side portion of the attachment protrusion 96 of the camera 22 is inserted into the insertion chamber 94 of the second cover 30B, the attachment protrusion 96 and the insertion chamber 94 are covered and hidden by the covering plate 92 of the first cover 30A. Thus, it is possible to prevent the attachment protrusion 96 and the insertion chamber 94 from being viewed.

In the fifth embodiment and the sixth embodiment, the camera 22 (including the attachment protrusion 96 according to the sixth embodiment) may be brought into contact (specifically, surface contact) with at least one of the upper wall or the peripheral wall of the base cover 30.

In the first to sixth embodiments, the base cover 30 includes two component bodies (the first cover 30A and the second cover 30B). However, the base cover 30 may include one component body, or three or more component bodies (three or more component bodies in the sixth embodiment).

In the first to sixth embodiments, the base 14 is connected to the side door 12 via the stud bolt 16 (the connection portion). However, the base 14 may be connected to the side door 12 via another connection portion (for example, a fastening means other than the stud bolt 16, such as a screw or a bolt).

In the first to sixth embodiments, each of the vehicle camera devices 10, 50, 60, 70, 80, 90 is installed on the side door 12 of the vehicle. However, each of the vehicle camera devices 10, 50, 60, 70, 80, 90 may be installed in another portion (for example, a fender) of the vehicle.

In the first to sixth embodiments, the mirror mechanism 40 is provided in the vehicle camera devices 10, 50, 60, 70, 80, 90. However, the mirror mechanism 40 need not be provided in the vehicle camera devices 10, 50, 60, 70, 80, 90. In this case, the entire exposed portion of the base 14 from the vehicle body side may be covered by the base cover 30.

The disclosure of Japanese Patent Application No. 2020-013891, filed on Jan. 30, 2020, is incorporated herein by reference in its entirety.

1. A vehicle camera device, comprising:
a support body that is provided with a connection portion connected to a vehicle body side, and that is supported by the vehicle body side; and
a camera mechanism that is configured to perform imaging, and heat generated by the camera mechanism being transferred to the vehicle body side via the connection portion.

2. The vehicle camera device according to claim 1, further comprising an attachment portion that is provided at the support body, to which the camera mechanism is attached, whereupon the camera mechanism is attached to the support body, and that is configured to transfer the heat generated by the camera mechanism to a side of the connection portion.

3. The vehicle camera device according to claim 2, wherein the attachment portion is attached to the support body by a biasing force.

4. The vehicle camera device according to claim 1, further comprising a connection member that is connected to the camera mechanism, and that is configured to transfer the heat generated by the camera mechanism to a side of the connection portion.

5. The vehicle camera device according to claim 4, wherein the connection member is connected to the camera mechanism by a biasing force.

6. A vehicle camera device, comprising:
a support body that is supported by a vehicle body side;
a covering body that is configured to cover the support body; and
a camera mechanism that is provided adjacent to an outer peripheral wall of the covering body, in the covering body, that is configured to perform imaging, and heat generated by the camera mechanism being transferred to an outside of the covering body via the outer peripheral wall of the covering body.

7. The vehicle camera device according to claim 6, further comprising a plurality of component bodies each of which is a component of the covering body, and between which the camera mechanism is assembled, whereupon the camera mechanism is attached to the covering body.

8. The vehicle camera device according to claim 7, further comprising a covering portion that is provided at the outer peripheral wall of the covering body, and that is configured to cover a portion at which the camera mechanism is assembled between the plurality of component bodies.

9. The vehicle camera device according to claim 6, further comprising an arrangement body that is arranged outside the covering body, the outer peripheral wall of the covering body being arranged between the arrangement body and the camera mechanism.
